(19) United States
(12) Patent Application Publication
(10) Pub. No.: US 2014/0124064 A1
(43) Pub. Date: May 8, 2014

(54) RAW MATERIAL VAPORIZING AND SUPPLYING APPARATUS

(71) Applicant: Fujikin Incorporated, Osaka (JP)

(72) Inventors: Atsushi Hidaka, Osaka (JP); Kaoru Hirata, Osaka (JP); Masaaki Nagase, Osaka (JP); Ryousuke Dohi, Osaka (JP); Kouji Nishino, Osaka (JP); Nobukazu Ikeda, Osaka (JP)

(73) Assignee: FUJIKIN INCORPORATED, Osaka (JP)

(21) Appl. No.: 14/065,078

(22) Filed: Oct. 28, 2013

Related U.S. Application Data
(63) Continuation-in-part of application No. PCT/JP2012/001117, filed on Feb. 20, 2012.

(30) Foreign Application Priority Data
Apr. 28, 2011 (JP) 2011-100446

(51) Int. Cl. C23C 16/455

(52) U.S. Cl. CPC C23C 16/45512
USPC 137/511

(57) ABSTRACT

A raw material vaporizing and supplying apparatus includes a carrier gas supply source, a source tank storing raw material, a flow passage supplying carrier gas to an internal upper space portion of the source tank, an automatic pressure regulating device installed on the flow passage, controlling pressure in the internal upper space portion to a set pressure, another flow passage supplying mixed gas (a mixture of raw material steam and carrier gas) from the internal upper space portion to a process chamber, a flow control system installed on this other flow passage, and automatically regulates a flow rate of the mixed gas supplied to the process chamber to a set flow rate, and a constant temperature heating unit that heats the source tank, a portion of the automatic pressure regulating device, a portion of the flow control system, the pipe passage, and the other pipe passage, to a set temperature.

This is a Continuation-in-Part Application in the United States of International Patent Application No. PCT/JP2012/001117 filed Feb. 20, 2012, which claims priority on Japanese Patent Application No. 2011-100446, filed Apr. 28, 2011. The entire disclosures of the above patent applications are hereby incorporated by reference.

### FIELD OF THE INVENTION

The present invention relates to an improvement in a raw material vaporizing and supplying apparatus of semiconductor manufacturing equipment using so-called “metalorganic chemical vapor deposition” (hereinafter called MOCVD), and, more particularly, relates to a raw material vaporizing and supplying apparatus that is capable of supplying a raw material steam of all raw materials (of not only a liquid raw material but also a solid raw material), or a raw material with low steam pressure, and the raw material vaporizing and supplying apparatus serves to make possible control of a mixture ratio of raw material steam and a carrier gas by regulating the internal pressure in a source tank, and is capable of efficiently manufacturing high-quality semiconductors by supplying a mixed gas whose flow rate is controlled to be a set flow rate with a high degree of accuracy, to a process chamber.

### BACKGROUND OF THE INVENTION

### Description of the Related Art

The present inventors have previously developed a raw material vaporizing and supplying apparatus, as shown in FIG. 6, as a raw material vaporizing and supplying apparatus for semiconductor manufacturing equipment by the MOCVD method, and disclosed this apparatus (See Japanese Patent No. 4605790).

That is, in FIG. 6, reference symbol 1 denotes a carrier gas supply source, reference symbol 2 denotes a decompression unit, reference symbol 3 denotes a thermal type mass flow control system (mass flow controller), reference symbol 4 denotes a raw material (a liquid raw material such as Al(CH₃)₃ or a supported sublimation solid raw material such as Pb(dpm)₂), reference symbol 5 denotes a source tank, reference symbol 6 denotes a constant temperature heating unit, reference symbols 7, 9 and 10 denote valves, reference symbol 8 denotes an introduction pipe, reference symbol 11 denotes a process chamber, reference symbol 14 denotes a vacuum pump, reference symbol 15 denotes an automatic pressure regulating device for the inside of the source tank, reference symbol 16 denotes an arithmetic and control unit, reference symbol 17 denotes an input terminal for a set pressure signal, reference symbol 18 denotes an output terminal for a detection pressure signal, reference symbol G₁ denotes a carrier gas such as Ar, reference symbol G₄ denotes saturated steam of the raw material, reference symbol G₀ denotes a mixed gas of the carrier gas G₁ and the raw material steam G₄, reference symbol P₀ denotes a pressure detector of the mixed gas G₀, reference symbol T₀ denotes a temperature detector of the mixed gas G₀, reference symbol CV denotes a piezoelectric element driving control valve, and reference symbol G₅ denotes another raw material, for example, another raw material gas (such as PH₃) which is combined with Al(CH₃)₃ or the like, so as to form a crystalline thin film on a substrate 13.

In the raw material vaporizing and supplying apparatus, pressure PG₁ of the carrier gas G₁, which is supplied to the inside of the source tank 5, is set to a predetermined pressure value by the decompression unit 2, and its supply flow rate is set to a predetermined value by the thermal type mass flow control system (mass flow controller) 3. Furthermore, the portion of the automatic pressure regulating device 15 for the source tank from which the arithmetic and control unit 16 is eliminated is heated and kept at a high temperature of about 150° C. by operation of the constant temperature heating unit 6.

In the raw material vaporizing and supplying apparatus of FIG. 6, the supply quantity of the carrier gas G₁ is set to a set value by the thermal type mass flow control system 3, and the temperature of the source tank 5 is set to a set value, and moreover, the internal pressure of the source tank 5 (the pressure of the mixed gas G₀) is kept to a set value by the automatic pressure regulating device 15, respectively, thereby supplying the mixed gas G₀ of a constant mixture ratio with a constant flow rate to the process chamber 11 through the control valve CV. This provides highly accurately control for a predetermined flow rate value, which is proportional to a flow rate set by the thermal type mass flow control system 3.

Furthermore, because the source tank 5, the control valve CV of the automatic pressure regulating device 15, and the like, are heated and kept at a high temperature of 150° C., the pressure of the saturated steam G₄ of the raw material 4 in the source tank 5 is increased. Therefore, it is possible to sufficiently respond to the requests of increasing a supply quantity of the steam G₄ to the side of the process chamber 11, and makes the mixed gas G₀ at a high temperature, thereby more completely preventing condensation of the raw material saturated steam G₄ in the supply line L₁ for the mixed gas G₀.

FIG. 7 shows the relationship of a flow rate A (sccm) of the carrier gas G₁ in the raw material vaporizing and supplying apparatus using the valve ring system of FIG. 6, the internal pressure Ptank (Torr) of the source tank 5, the raw material steam pressure P_{M}o (Torr), and a flow rate X (sccm) of the raw material, and a supply flow rate Q of the mixed gas G₀ to the chamber is Q=(A+X)(sccm). Sccm denotes standard cubic centimeter per minute.

In other words, because the flow rate X of the raw material is proportional to the raw material steam pressure P_{M}o in the source tank, and the supply flow rate Q=A+X of the mixed gas G₀ is proportional to the internal pressure Ptank in the source tank, the following relationship is formed:

(The flow rate X of raw material)/(The mixed gas supply flow rate(A+X))=(The raw material steam pressure P_{M}o in the source tank)/(The internal pressure Ptank in source tank),

i.e., the relationship as shown in Formula (1):

X×Ptank=(A+X)×P_{M}o (1).

From the Formula (1), the flow rate X of the raw material is as shown in Formula (2):

X=A×P_{M}o/(P tank−P_{M}o) (2).

As is clear from the above-described Formula (2), the flow rate X of the raw material is determined by the carrier gas flow rate A, the pressure Ptank in the source tank, and the raw material steam pressure (partial pressure) P_{M}o. Furthermore, the internal pressure Ptank in the source tank is changed according to a temperature in the source tank, and further, a raw material quantity carried out by air bubbles changes according to a liquid level height of the raw material in the tank, respectively.

Accordingly, a concentration of the raw material in the mixed gas G₀ is to be determined by using the carrier gas flow rate A, the internal pressure Ptank in the source tank, the temperature t in the source tank, and the liquid level height of the raw material in the source tank (raw material concentration in air bubbles) as parameters.

FIG. 8 shows the interrelationship of a TEOS flow rate X and a mixed gas supply flow rate (total flow rate Q=A+X) to the chamber in the case of the raw material vaporizing and supplying apparatus shown in FIG. 6, where the raw material is TEOS (tetraethoxysilane), the flow rate A of the carrier gas (Ar) is A=10 sccm, the internal pressure Ptank in the source tank=1000 Torr (i.e., the control pressure of the automatic pressure regulating device 15), the TEOS steam pressure is 470 Torr (at 150° C.), and the TEOS flow rate is X (sccm).

From the Formula (2), the TEOS flow rate becomes X=A×P_{TEOS}/(Ptank−P_{TEOS})=10×470(1000−470)=8.8 sccm. That is, the TEOS flow rate is 8.8 sccm, the carrier gas (Ar gas) flow rate X=10 sccm, and the total flow rate (A+X)=18.8 sccm, and the flow rate Q (total flow rate A+X) of the mixed gas G₀ supplied to the chamber 11 and the carrier gas flow rate A are different values. Therefore, it is not possible to directly control the flow rate of the mixed gas G₀ by the thermal type mass flow control system 3.

However, the raw material vaporizing and supplying apparatus shown in FIG. 6 described above is configured to highly accurately control an inflow flow rate of the carrier gas G₁ into the source tank 5 to a predetermined flow rate by the mass flow control system 3, and to heat, using constant-temperature, the source tank and the like at a maximum of 250° C., thereby stimulating evaporation of the raw material in the source tank, and furthermore, to highly accurately control the pressure P₀ of the mixed gas G₀ of the carrier gas G₁ and the raw material steam G₄ in the source tank 5 to a predetermined value by the automatic pressure regulating device. Therefore, the flow rate of the mixed gas G₀ flowing into the process chamber 11 and the mixture ratio of the carrier gas G₁ in the mixed gas G₀ and the steam G₄ are maintained constant, and a desired quantity of the raw material 4 is always stably supplied to the process chamber. As a result, the beneficial effect that it is possible to significantly improve the quality of manufactured semiconductor products and reduce defective goods is achieved.

However, in the above-described raw material vaporizing and supplying apparatus of the bubbling method, as well, there still remain many unsolved problems. First, one problem is due to the fact that because the expensive thermal type mass flow control system 3 is used, not only it is difficult to achieve lowering of the manufacturing cost of the raw material vaporizing and supplying apparatus, it is also necessary to highly accurately control the supply pressure of the carrier gas supplied from the carrier gas source 1 to the thermal type mass flow control system 3, which increases the equipment cost of the decompression unit 2. Furthermore, there is a problem that it is not possible to directly control the flow rate of the mixed gas G₀ by the thermal type mass flow control system 3.

The second problem is due to the fact that because the apparatus adopts the bubbling method, it is difficult to stably supply a raw material steam in the case of a solid raw material, and it is additionally difficult to stably supply a raw material steam in the case of a raw material with low steam pressure, which often makes it unstable to supply a mixed gas to the process chamber. In other words, the supply of raw materials that can be vaporized is limited, that is, there is a problem that it is not possible to vaporize and supply some of raw materials.

The third problem is due to the fact that the concentration of the raw material steam in the mixed gas G₀ significantly fluctuates according to a fluctuation in raw material liquid level in the source tank, which makes it difficult to control the concentration of the raw material steam. In other words, the fact is that because the raw material steam adheres to, or is contained in, air bubbles during a bubble flow that rises in the raw material liquid, and which are taken out to an internal upper space portion in the source tank in accordance with the bubbling method, the quantity of the raw material steam G₄ taken out to the internal upper space portion in the source tank 5 significantly fluctuates according to a liquid level height of the raw material 4. Consequently, the concentration of the raw material in the mixed gas G₀ changes according to the fluctuation in liquid level height of the raw material.

The fourth problem is due to the fact that because the carrier gas flow rate A on the inlet side and the mixed gas flow rate (total flow rate) Q on the outlet side are different from each other, highly accurate flow control of the mixed gas flow rate is difficult, and it is not easy to highly accurately control the internal pressure in the source tank. As a result, it is not easy to regulate a raw material concentration directly relating to the partial pressure of the raw material steam in the mixed gas in the tank. In other words, because it is difficult to stably supply the mixed gas G₀ while keeping a raw material concentration constant, an expensive monitor device for raw material concentration is required, or because it is not easy to calculate a quantity of the raw material to be taken out of the inside of the source tank, it requires a lot of trouble to manage a residual quantity of the raw material in the source tank.

### CITATION LIST

### Patent Document

Patent Document 1: Japanese Patent No. 4605790

### Problems to be Solved by the Invention

It is a main object of the present invention to solve the problems described above in the raw material vaporizing and supplying apparatus of Japanese Patent No. 4605790, that is, the problems including (a) that it is difficult to lower the manufacturing cost because a thermal type mass flow control system is used, (b) supplied raw materials that can be vaporized are limited, (c) it is difficult to highly accurately control the flow rate of the mixed gas that is supplied to the chamber, and to regulate the raw material concentration in the mixed gas, and the like. Therefore, it is an object of the present invention to provide vaporizing and supplying of raw material in which it is possible to achieve lowering of the manufacturing cost, and wherein it is possible to stably vaporize and supply all raw materials with a simple structure, and additionally, it is possible to easily and highly accurately control the mixed gas flow rate that is supplied to the chamber and the raw material concentration in the mixed gas.

### SUMMARY OF THE INVENTION

### Means for Solving the Problems

In accordance with a first aspect of the invention, a basic configuration of the invention includes a carrier gas supply source, a source tank in which a raw material is stored, a flow passage L₁ through which a carrier gas G₁ from the carrier gas supply source is supplied to an internal upper space portion of the source tank, an automatic pressure regulating device that is installed along the way of the flow passage L₁, and controls pressure in the internal upper space portion of the source tank to a set pressure, a flow passage L₂ through which a mixed gas G₀, which is a mixture of raw material steam generated from the raw material and the carrier gas, is supplied from the internal upper space portion of the source tank to a process chamber, a flow control system that is installed along the way of the flow passage L₂, and that automatically regulates a flow rate of the mixed gas G₀ that is supplied to the process chamber, to a set flow rate, and a constant temperature heating unit that heats up the source tank, the flow passage L₁, and the flow passage L₂ to a set temperature, and the mixed gas G₀ is supplied to the process chamber while controlling the internal pressure of the internal upper space portion of the source tank to a desired pressure.

In accordance with a second aspect of the invention, in the invention according to the first aspect, the flow passage L₁ and the flow passage L₂ are composed of pipe passages through which a fluid flows, and distribution passages inside the automatic pressure regulating device and the flow control system.

In accordance with a third aspect of the invention, in the invention according to the first aspect, the automatic pressure regulating device that controls pressure in the internal upper space portion of the source tank is composed of a control valve CV₁, a temperature detector T₀ and a pressure detector P₀, which are provided on the downstream side of the control valve CV₁, an arithmetic and control unit that performs a temperature correction of a detection value from the pressure detector P₀, on the basis of a detection value from the temperature detector T₀, to compute the pressure of the carrier gas G₁, and which outputs a control signal Pd for controlling opening and closing of the control valve CV₁ in a direction in which a difference between a pressure set in advance, and the computed pressure lessens by comparing the both of them, and a heater that heats up the distribution passages through which the carrier gas flows, to a predetermined temperature.

In accordance with a fourth aspect of the invention, in the invention according to the first aspect, the flow control system that supplies the mixed gas G₀ from the internal upper space portion of the source tank to the process chamber is composed of a control valve CV₂, a temperature detector T and a pressure detector P, which are provided on the downstream side of the control valve CV₂, an orifice that is provided on the downstream side of the pressure detector P, an arithmetic and control unit that performs a temperature correction of a flow rate of the mixed gas G₀ computed by use of a detection value from the pressure detector P, on the basis of a detection value from the temperature detector T, to compute a flow rate of the mixed gas G₀, and which outputs a control signal Pd for controlling opening and closing of the control valve CV₂ in a direction in which a difference between a mixed gas flow rate, set in advance, and the computed mixed gas flow rate lessens by comparing the both of them, and a heater that heats up the distribution passages through which the mixed gas flows, to a predetermined temperature.

In accordance with a fifth aspect of the invention, in the invention according to the first aspect, the raw material is a liquid raw material, or a solid raw material that is supported by a porous support.

Generally speaking then, in accordance with a first non-limiting illustrative embodiment of the present invention, a raw material vaporizing and supplying apparatus is provided, wherein the apparatus includes: (a) a carrier gas supply source; (b) a source tank in which a raw material is stored; (c) a flow passage L₁ through which a carrier gas G₁ from the carrier gas supply source is supplied to an internal upper space portion of the source tank; (d) an automatic pressure regulating device that is installed along the way of the flow passage L₁, and controls pressure in the internal upper space portion of the source tank to a set pressure; (e) a flow passage L₂ through which a mixed gas G₀, which is a mixture of raw material steam generated from the raw material and the carrier gas, is supplied from the internal upper space portion of the source tank to a process chamber; (f) a flow control system that is installed along the way of the flow passage L₂, and automatically regulates a flow rate of the mixed gas G₀ that is supplied to the process chamber to a set flow rate; and (g) a constant temperature heating unit that heats up the source tank, the flow passage L₁, and the flow passage L₂ to a set temperature, wherein the raw material vaporizing and supplying apparatus supplies the mixed gas G₀ to the process chamber while controlling the internal pressure of the internal upper space portion of the source tank to a desired pressure. In accordance with a second non-limiting, illustrative embodiment of the present invention, the first non-limiting embodiment is modified so that the flow passage L₁ and the flow passage L₂ are composed of pipe passages through which a fluid flows, and distribution passages inside the automatic pressure regulating device and the flow control system. In accordance with a third non-limiting, illustrative embodiment of the present invention, the first non-limiting embodiment is modified so that the automatic pressure regulating device that controls pressure in the internal upper space portion of the source tank is composed of a control valve CV₁, a temperature detector T₀ and a pressure detector P₀, which are provided on the downstream side of the control valve CV₁, an arithmetic and control unit that performs a temperature correction of a detection value from the pressure detector P₀, on the basis of a detection value from the temperature detector T₀, to compute the pressure of the carrier gas G₁, and which outputs a control signal Pd for controlling opening and closing of the control valve CV₁ in a direction in which a difference between a pressure set in advance and the computed pressure lessens by comparing the both of them, and a heater that heats up the distribution passages through which the carrier gas flows, to a predetermined temperature.

In accordance with a fourth, non-limiting embodiment of the present invention, the first non-limiting embodiment or the third non-limiting embodiment is modified so that the flow control system that supplies the mixed gas G₀ from the internal upper space portion of the source tank to the process chamber is composed of a control valve CV₂, a temperature detector T and a pressure detector P, which are provided on the downstream side of the control valve CV₂, an orifice that is provided on the downstream side of the pressure detector P, an arithmetic and control unit that performs a temperature correction of a flow rate of the mixed gas G₀ computed by use of a detection value from the pressure detector P, on the basis of a detection value from the temperature detector T, to compute a flow rate of the mixed gas G₀, and which outputs a control signal Pd for controlling opening and closing of the control valve CV₂ in a direction in which a difference between a mixed gas flow rate set in advance and the computed mixed gas flow rate lessens by comparing the both of them, and a heater that heats up the distribution passages through which the mixed gas flows to a predetermined temperature. In accordance with a fifth non-limiting, illustrative embodiment of the invention, the first non-limiting embodiment is modified so that the raw material is a liquid raw material or a solid raw material that is supported by a porous support.

### Effect of the Invention

The present invention is configured to keep a temperature in the source tank at a set value, and to control the pressure in the internal upper space portion of the source tank by using the automatic pressure regulating device, and to supply a mixed gas from the internal upper space portion of the source tank to the chamber while controlling its flow rate by means of the pressure type flow control system. Thus, the present invention operates differently from the bubbling method because the steam pressure P_{M}o of the raw material steam in the source tank is maintained as saturated steam at a set temperature by heating the raw material in the source tank, and the total pressure Ptank in the internal upper space portion of the source tank is controlled to be at a set value by using the automatic pressure regulating device, in combination with the fact that the raw material flow rate X in the mixed gas G₀ is directly proportional to a ratio of the raw material steam pressure P_{M}o and the tank internal pressure Ptank. Consequently, by means of the present invention, it is possible to easily, highly accurately, and stably control the raw material flow rate X.

Furthermore, because the flow rate that is controlled by the flow control system and the mixed gas flow rate Q so as to converge and become the same value, it is possible to highly accurately perform flow control of the mixed gas G₀. Also, because it is additionally possible to easily calculate the raw material flow rate X, it is possible to easily know a residual quantity of the raw material in the source tank, which simplifies management of the raw material.

### BRIEF DESCRIPTION OF THE DRAWINGS

FIG. 1 is a schematic, systematic diagram showing a configuration of a raw material vaporizing and supplying apparatus according to an embodiment of the present invention.

FIG. 2 is an explanatory schematic diagram of a configuration of an automatic pressure regulating device.

FIG. 3 is an explanatory schematic diagram of a configuration of a pressure type flow control system.

FIG. 4 is an explanatory schematic diagram showing the relationship between a supply flow rate of a carrier gas G₁ and a supply flow rate of a mixed gas G₀ to a chamber in accordance with the present invention.

FIG. 5 is an explanatory schematic diagram showing the relationship between a supply flow rate of the carrier gas G₁ and a supply flow rate of the mixed gas G₀ according to an embodiment of the present invention.

FIG. 6 is a schematic systematic diagram showing a configuration of a conventional prior art raw material vaporizing and supplying apparatus.

FIG. 7 is an explanatory schematic diagram showing the relationship between a supply flow rate of the carrier gas G₁ and a supply flow rate of the mixed gas G₀ in the conventional, prior art raw material vaporizing and supplying apparatus.

FIG. 8 is an explanatory schematic diagram showing the relationship between a supply flow rate of the carrier gas G₁ and a supply flow rate of the mixed gas G₀ according to a conventional prior art embodiment.

### DETAILED DESCRIPTION OF THE PREFERRED EMBODIMENTS

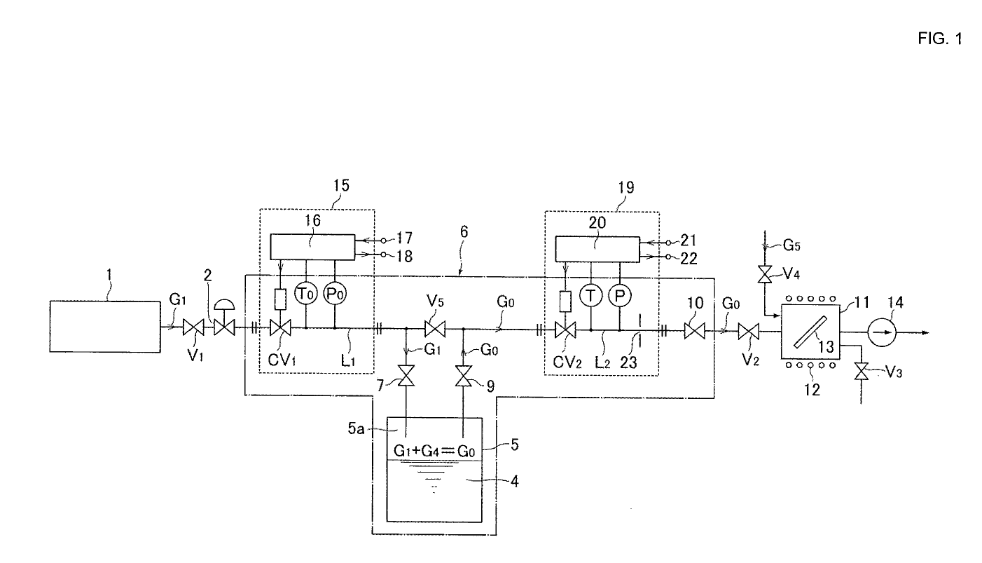

Hereinafter, an embodiment of the present invention will be described with reference to the drawings, wherein like parts are designated using like references. FIG. 1 illustrates a configuration systematic diagram of a raw material vaporizing and supplying apparatus according to an embodiment of the present invention, wherein the raw material vaporizing and supplying apparatus is composed of a carrier gas supply source 1, a source tank 5 that contains a raw material 4, an automatic pressure regulating device 15 that controls the internal pressure of the source tank 5, a flow control system 19 that regulates a supply flow rate of a mixed gas G₀, which is supplied to a process chamber 11, a constant temperature heating unit 6 that heats up the distribution passages of the automatic pressure regulating device 15 and the flow control system 19, the source tank 5, and the like.

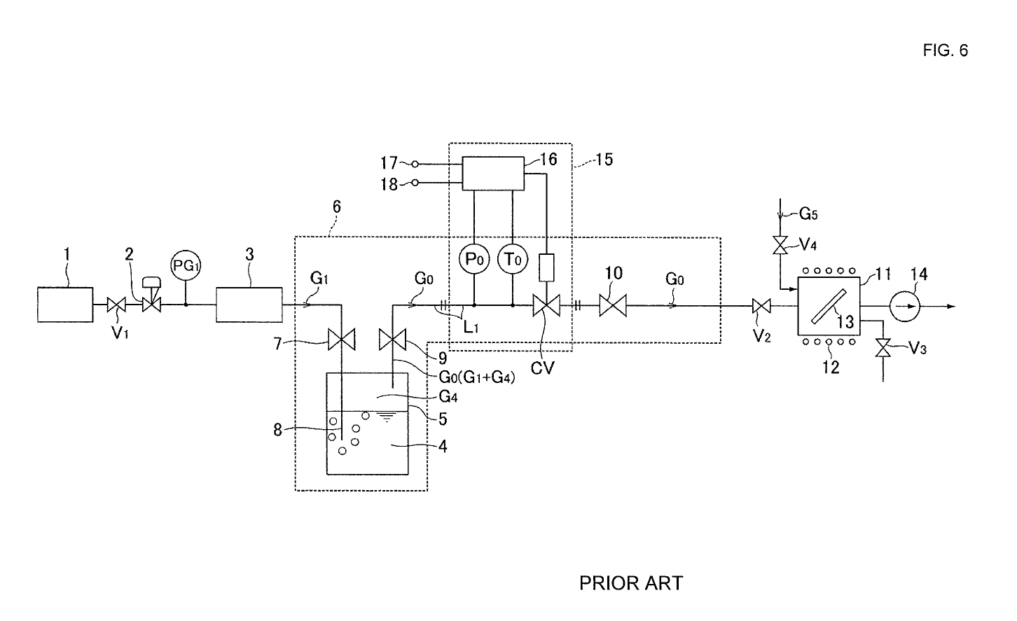

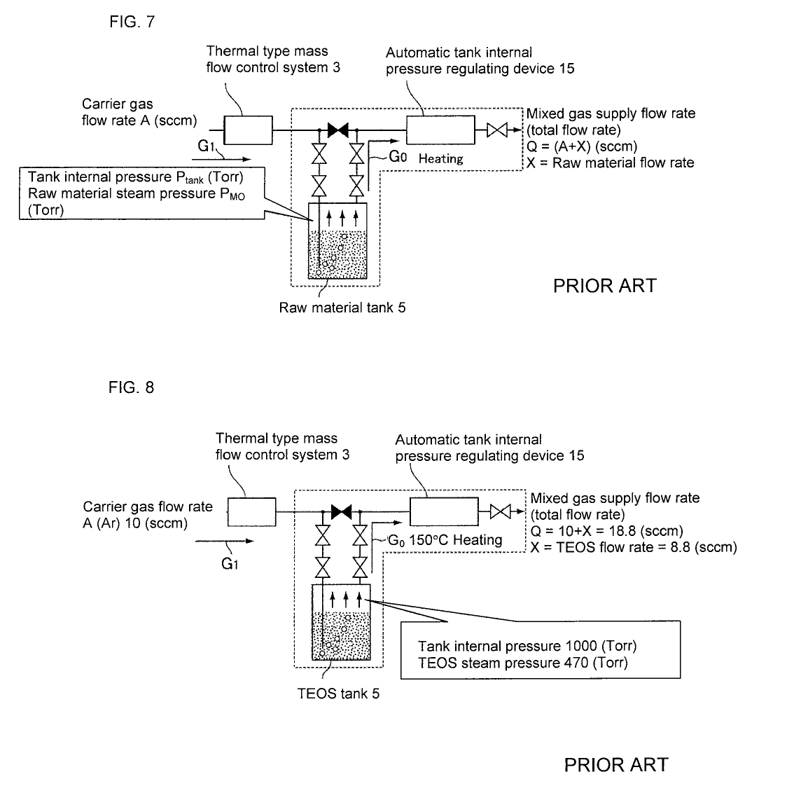

In addition, in FIG. 1, the same reference symbols are given to the same component members as those of the raw material vaporizing and supplying apparatus shown in FIG. 6, and except for three points of fact, namely, (i) that the internal pressure of the source tank 5 is controlled by use of the automatic pressure regulating device 15, in accordance with the present invention, which regulates the pressure of an internal upper space portion 5a of the source tank 5 in place of the thermal type mass flow control system 3 of the conventional apparatus of FIG. 6, that controls the supply flow rate of the carrier gas G₁ supplied to the source tank 5 in the conventional raw material vaporizing and supplying apparatus. The second and third distinguishing features include (ii) the fact that the carrier gas G₁, in accordance with the present invention, is directly supplied to the internal upper space portion 5a of the source tank 5 without performing bubbling, and (iii) the fact that the mixed gas G₀ at a predetermined flow rate is supplied to the chamber 11 while performing flow control of the mixed gas G₀ from the source tank 5 by the flow control system 19. Otherwise, other configurations and component members are mostly the same as those in the case of the conventional raw material vaporizing and supplying apparatus of FIG. 6.

Referring to FIG. 1, the carrier gas G₁, such as Ar supplied from the carrier gas supply source 1, is supplied to the internal upper space portion 5a of the source tank 5 through a control valve CV₁ of the automatic pressure regulating device 15, and the internal pressure of the source tank 5 is controlled to be a predetermined pressure value by using the automatic pressure regulating device 15 as will be described later.

On the other hand, the inside of the source tank 5 is filled with an appropriate quantity of liquid material 4 (for example, an organic metallic compound, or the like, such as TEOS), or a solid raw material (for example, a solid raw material in which an organic metallic compound is supported by a porous support), which is heated up to 150° C. to 250° C. by a heater (not shown) within the constant temperature heating unit 6, thereby generating saturated steam G₄ of the raw material 4 at that heating temperature. Consequently, the inside of the internal upper space portion 5a of the source tank 5 is filled with the saturated steam G₄.

The generated saturated steam G₄ of the raw material 4 and the carrier gas G₁ are mixed in the internal upper space portion 5a of the source tank 5, and this mixed gas G₀ flows into a control valve CV₂ of the flow control system 19 through a valve 9. As will be described later, the mixed gas G₀ is controlled to be at a predetermined flow rate by the flow control system 19, and is supplied to the process chamber 11.

The automatic pressure regulating device 15 is provided on the downstream side of the carrier gas supply source 1, that is, so it may automatically regulate the pressure of the internal upper space portion 5a of the source tank 5 to a set value. More specifically, pressure P₀ and a temperature T₀ of the carrier gas G₁ are detected in a flow passage L₁ on the inflow side to the inside of the source tank 5, and a temperature correction for the pressure is performed by use of the detected pressure P₀ and detected temperature T₀ in an arithmetic and control unit 16, and, in addition, the corrected pressure value and the set pressure value from a set input terminal 17 are compared, in order to generate a control signal Pd that is used to control the opening and closing of the control valve CV₁ in a direction in which the deviation between both the corrected pressure value and the set pressure value becomes zero. In other words, in accordance with the present invention, the arithmetic and control unit 16 compares the temperature corrected value computed by the arithmetic and control unit 16 to the set pressure value, which is inputted from input terminal 17, and the arithmetic and control unit 16 generates a control signal Pd that is outputted to the control opening and closing of the control valve CV₁ in a manner needed to bring the difference between the computed corrected pressure value and the set pressure value to zero.

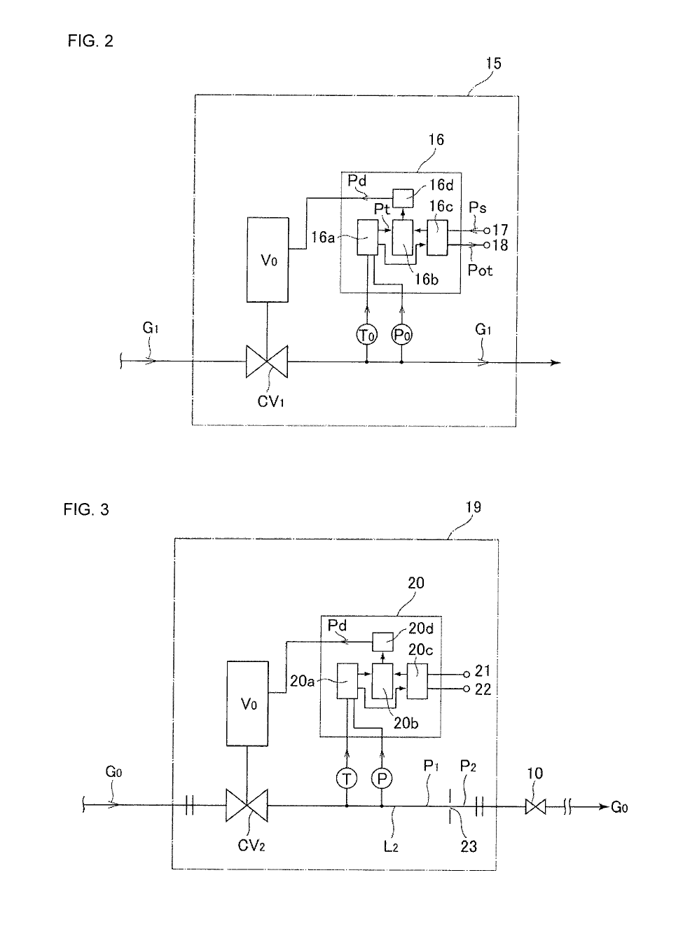

FIG. 2 shows a block configuration of the automatic pressure regulating device 15, and the arithmetic and control unit 16 thereof is composed of a temperature correction circuit 16a, a comparison circuit 16b, an input-output circuit 16c, an output circuit 16d, and the like. The detection values from the pressure detector P₀ and the temperature detector T₀ are converted into digital signals, to be input to the temperature correction circuit 16a, and the detection pressure P₀ is corrected to a detection pressure Pt, to be thereafter input to the comparison circuit 16b. Furthermore, an input pressure signal Ps of the set pressure is input from the terminal 17, and converted into a digital value in the input-output circuit 16c, to be thereafter input to the comparison circuit 16b, and the digital value is compared with the temperature-corrected detection pressure signal Pt from the temperature correction circuit 16a. Then, in the case where the set pressure input signal Ps is higher than the temperature-corrected detection pressure signal Pt, a control signal Pd is output to the drive unit of the control valve CV₁. Consequently, the control valve CV₁ is driven toward the valve-opening direction, so as to be driven toward the valve-opening direction until a difference (Ps−Pt) between the set pressure input signal Ps and the temperature-corrected detection pressure signal Pt becomes zero.

On the other had, in the case where the set pressure input signal Ps is lower than the temperature-corrected detection pressure signal Pt, a control signal Pd is output to the drive unit of the control valve CV₁, and the control valve CV₁ is driven toward the valve-closing direction, thereby continuing the driving toward the valve-closing direction until a difference Ps−Pt between the two pressure signals becomes zero. In this way, an appropriate control signal Pd is generated by the output circuit 16d of the arithmetic and control unit 16 so that the temperature-corrected detection pressure signal Pt and the set pressure corresponding to the input pressure signal Ps are made to converge so that the difference (Ps−Pt) between the set pressure input signal Ps and the temperature-corrected detection pressure signal Pt becomes zero.

The flow control system 19 is provided at a flow passage L₂ for controlling deviation of the mixed gas G₀ on the downstream side of the source tank 5, and as shown in the configuration diagram of FIG. 3, the configuration of the flow control system 19 is the same as the case of the automatic pressure regulating device 15, except for the fact that the mixed gas G₀ flowing through the control valve CV₂ is flowed out through an orifice 23. Accordingly, here, detailed descriptions thereof are omitted, except to say that the flow control system 19, and the arithmetic and control unit 20 thereof is composed of a temperature correction circuit 20a, a comparison circuit 20b, an input-output circuit 20c, an output circuit 20d, and the like. The detection values from the pressure detector P and the temperature detector T are converted into digital signals, to be input to the temperature correction circuit 20a, and the detection pressure P is corrected to a detection pressure Pt, to be thereafter input to the comparison circuit 20b. Furthermore, an input pressure signal Ps of the set pressure is input from the terminal 21, and converted into a digital value in the input-output circuit 20c, to be thereafter input to the comparison circuit 20b, and the digital value is compared with the temperature-corrected detection pressure signal Pt from the temperature correction circuit 20a.

In addition, in the arithmetic and control unit 20 of the flow control system 19, a flow rate Q is computed as Q=KP₁ (K is a constant determined by the orifice) by use of the pressure detection value P, and the so-called temperature correction of the computed flow rate is performed with a detection value from the temperature detector T, and the temperature-corrected flow rate computed value and the set flow rate value are compared in the comparison circuit 20b, and a difference signal between them both is output as a control signal to the drive circuit of the control valve CV₂. Then, in the case where the set flow rate input signal Fs is higher than the computed temperature-corrected flow rate Ft, a control signal Pd is output to the drive unit of the control valve CV₂. Consequently, the control valve CV₂ is driven toward the valve-opening direction, so as to be driven toward the valve-opening direction until a difference (Fs−Ft) between the set flow rate input signal Fs and the computed temperature-corrected flow rate signal Ft becomes zero. On the other had, in the case where the set flow rate input signal Fs is lower than the computed temperature-corrected flow rate signal Ft, a control signal Pd is output to the drive unit of the control valve CV₂, and the control valve CV₂ is driven toward the valve-closing direction, thereby continuing the driving toward the valve-closing direction until a difference Fs−Ft between the two flow rate signals becomes zero. In this way, an appropriate control signal Pd is generated by the output circuit 20d of the arithmetic and control unit 20 so that the computed temperature-corrected flow rate signal Ft and the set flow rate corresponding to the input signal Fs at terminal 21 are made to converge so that the difference (Fs−Ft) between the set flow rate input signal Fs and the computed temperature-corrected flow rate signal Ft becomes zero.

The flow control system 19 itself is publicly-known as described above. Meanwhile, the flow control system 19 has the excellent feature that, in the case where the relationship that P₁/P₂ is greater than or equal to about 2 (the so-called critical condition) is maintained between the pressure P₂ on the downstream side of the orifice 21 (i.e., the pressure P₂ on the side of the process chamber) and the pressure P₁ on the upstream side of the orifice 21 (i.e., the pressure P₁ on the outlet side of the control valve CV₂), the flow rate Q of the mixed gas G₀ flowing through the orifice 21 is Q=KP₁, and it is possible to highly accurately control the flow rate Q by controlling the pressure P₁. Consequently, even when the pressure of the mixed gas G₀ on the upstream side of the control valve CV₂ is significantly changed, the flow control characteristics hardly change.

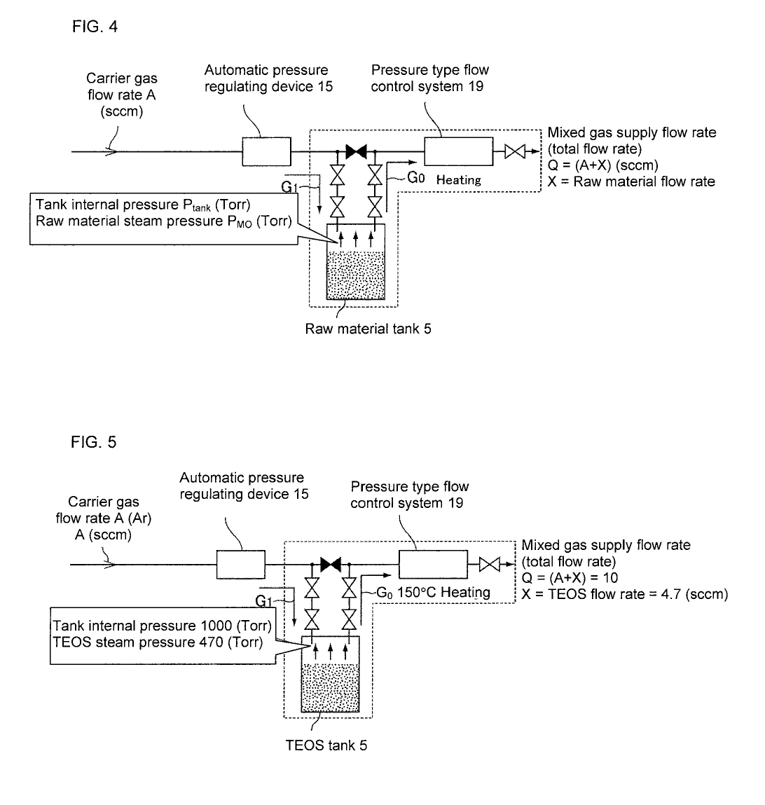

FIG. 4 shows the relationship between a flow rate A (sccm) of the carrier gas G₁, a total internal pressure Ptank (Torr) of the source tank 5, steam pressure (partial pressure) P_{M}o (Torr) of the raw material 4, and a flow rate X (sccm) of the raw material 4 in the raw material vaporizing and supplying apparatus according to the present invention using an automatic pressure regulating method. Q is the supply flow rate (sccm) of the mixed gas G₀ to the chamber 11, and is Q=A+X(sccm), and is a controlled flow rate in the flow control system 19.

In other words, the relational expression wherein, (the raw material flow rate X)/(the total flow rate Q)=(the raw material steam pressure (partial pressure) P_{M}o in the source tank)/(the total internal pressure Ptank in the source tank is established), and from this relational expression, the raw material flow rate X becomes X=(the total flow rate Q)×(the raw material steam pressure (partial pressure) P_{M}o in the source tank)/(the total internal pressure Ptank in the source tank). Consequently, it is possible to easily calculate the raw material flow rate X (i.e., a quantity of the raw material 4 taken out of the source tank 5) from the total flow rate Q, as well as from the raw material steam pressure P_{M}o, and from the total internal pressure Ptank in the tank.

Furthermore, as is clear from the relational expression of the raw material flow rate X, the raw material flow rate X (i.e., the raw material concentration in the mixed gas G₀) is determined by use of the internal pressure Ptank of the source tank, the raw material steam pressure P_{M}o, and the source tank internal temperature as parameters.

FIG. 5 shows a TEOS flow rate X in the mixed gas G₀ in the case of the raw material vaporizing and supplying apparatus according to the present invention, where the raw material is TEOS, and the carrier gas G₁ is argon (Ar), the mixed gas flow rate to the chamber is Q=10 sccm, the source tank total internal pressure is Ptank=1000 Torr (i.e., the source tank internal controlled pressure by the automatic pressure regulating device 15), the TEOS steam pressure is P_{M}o=470 Torr (in the case of the temperature of 150° C.), and the supply quantity of the carrier gas Ar is A sccm, which comes to the TEOS flow rate X(sccm)=Q×P_{TEOS}/Ptank=10×470/1000=4.7 sccm. As a result, the total supply flow rate of the mixed gas G₀ becomes Q=A+X=10 sccm, the TEOS flow rate becomes X=4.7 sccm, and the flow rate A of the carrier gas (Ar) G₁ becomes A=5.3 sccm.

In addition, the primary specifications of the automatic pressure regulating device 15 for regulation of the source tank internal pressure, which is used for the present embodiment are shown hereinafter in Table 1, and the maximum operating temperature is 150° C., and the maximum pressure (Full Scale (F.S.) pressure) at a flow rate of 500 sccm (N₂) is 133.3 kPa abs.

TABLE 1
Primary specifications of the automatic pressure regulating device

| | |
|---|---|
| Name | Automatic pressure regulating device |
| Pressure range | 133.3 kPa abs. (1000 Torr) |
| (F.S. pressure) | Flow rate: 500 sccm (N₂) |
| Secondary side pressure | Lower than or equal to a set regulated pressure |
| Withstanding pressure | 0.35 Mpa G |
| External leak level | Lower than or equal to 1 × 10⁻¹⁰ Pa m³/sec |
| Internal leak level | Lower than or equal to 1% F.S. |
| | (At supply pressure of 1000 kPa abs.) |
| Accuracy assurance | 15° C. to 150° C. |
| temperature range | |
| Available temperature | 0° C. to 160° C. |
| range | |
| Environmental | 15° C. to 50° C. |
| temperature | |
| Gas contact member | SUS316L, Nickel-cobalt alloy (diaphragm), |
| material | hastelloy, C-22 (pressure sensor) |
| Mounting posture | Available in all directions |

Furthermore, the primary specifications of the flow control system 19 used for the present embodiment are compiled in Table 2, which has similarities to the primary specifications of the automatic pressure regulating device 15 compiled in Table 1.

TABLE 2
Primary specifications of the flow control system

| | |
|---|---|
| Name | Flow control system |
| Flow Rate range | 133.3 kPa abs. (1000 Torr) |
| (F.S. flow rate) | Flow rate: 500 sccm (N₂) |
| Primary side pressure | Lower than or equal to 500 kPa abs |
| Withstanding pressure | 0.35 Mpa G |
| External leak level | Lower than or equal to 1 × 10⁻¹⁰ Pa m³/sec |
| Internal leak level | Lower than or equal to 1% F.S. |
| | (At supply pressure of 1000 kPa abs.) |
| Accuracy assurance | 15° C. to 150° C. |
| temperature range | |
| Available temperature | 0° C. to 160° C. |
| range | |
| Environmental temperature | 15° C. to 50° C. |
| Gas contact member | SUS316L, Nickel-cobalt alloy (diaphragm), |
| material | hastelloy, C-22 (pressure sensor) |
| Mounting posture | Available in all directions |

Moreover, because the control valves CV₁ and CV₂ used for the automatic pressure regulating device 15 and for the flow control system 19, respectively, may be exposed to increased operating temperature around 150° C. to 250° C., component members possessing specifications available for high-temperature use are used as the valve component members (such as a piezoelectric actuator and a disc spring). Likewise, an invar material is used as a diaphragm presser in consideration of thermal expansion of the respective component members, such as a piezoelectric element and valves, so it is possible to prevent occlusion of the flow passages due to expansion of the piezoelectric element drive unit. Furthermore, the storage case of the piezoelectric element drive unit is a perforated chassis, and the piezoelectric element drive unit, and the like, are structured to be air-coolable, thereby achieving a reduction in thermal expansion of the respective component parts of the piezoelectric valves. In addition, a cartridge heater or a mantle heater is mounted to the body portions of the control valves CV₁ and CV₂ so as to heat up the valve main bodies to a predetermined temperature (at a maximum of 250° C.). In addition, because the automatic pressure regulating device 15 and the flow control system 19 themselves are publicly-known, see Japanese Patent No. 4605790 and the like, detailed descriptions thereof are omitted here beyond what is explicitly described above.

In sum then, the present invention, which pertains to a raw material vaporizing and supplying apparatus, makes it possible to stably supply either a solid raw material or a liquid raw material at low steam pressure to a process chamber while precisely regulating a raw material concentration in a mixed gas of a carrier gas and a raw material gas, and additionally, under highly accurate flow control, makes it possible to easily manage a residual quantity of the raw material. Generally speaking, in accordance with the above description, a raw material vaporizing and supplying apparatus of the present invention includes a carrier gas supply source, a source tank in which a raw material is stored, a flow passage L₁ through which a carrier gas G₁ from the carrier gas supply source is supplied to an internal upper space portion of the source tank, an automatic pressure regulating device that is installed along the way of the flow passage L₁, and that controls pressure in the internal upper space portion of the source tank to a set pressure by regulating an opening degree of the control valve CV₁, a flow passage L₂ through which a mixed gas G₀ (which is a mixture of raw material steam generated from the raw material and the carrier gas) is supplied from the internal upper space portion of the source tank to a process chamber, a flow control system is installed along the way of the flow passage L₂, and the flow control system automatically regulates a flow rate of the mixed gas G₀ that is supplied to the process chamber, to a set flow rate by regulating an opening degree of the control valve CV₂, and a constant temperature heating unit is provided that heats up the source tank, a portion of the automatic pressure regulating device from which an arithmetic and control unit is eliminated (i.e., positioned so as not to be heated by the heating unit), a portion of the flow control system from which an arithmetic and control unit is eliminated (i.e., positioned so as not to be heated by the heating unit), a pipe passage L₁, and a pipe passage L₂, to a set temperature, and the invention is configured to supply the mixed gas G₀ to the process chamber while controlling the internal pressure of the internal upper space portion of the source tank to a desired pressure.

### INDUSTRIAL APPLICABILITY

The present invention is applicable not only as a raw material vaporizing and supplying apparatus used for the MOCVD method, but also to all gas supply apparatuses that are configured to supply gas from a pressurized reservoir source to a process chamber in semiconductor manufacturing equipment, chemical products manufacturing equipment, or the like. In the same way, the automatic pressure regulating device according to the present invention is widely applicable not only to a raw material vaporizing and supplying apparatus used for the MOCVD method, but also to a liquid supply circuit for semiconductor manufacturing equipment, chemical products manufacturing equipment, or the like, as an automatic pressure regulating device of a liquid supply source on the primary side.

### DESCRIPTION OF REFERENCE SYMBOLS

1: Carrier gas supply source
2: Decompression unit
3: Mass flow control system
4: Raw material
5: Source tank (container)
5a: Internal upper space portion of source tank
6: Constant temperature heating unit
7: Inlet valve
9: Outlet valve
10: Valve
11: Process chamber (crystalline growth furnace)
12: Heater
13: Substrate
14: Vacuum pump
15: Automatic pressure regulating device for source tank
16, 20: Arithmetic and control unit
16a, 20a: Temperature correction circuit
16b, 20b: Comparison circuit
16c, 20c: Input-output circuit
16d, 20d: Output circuit
17, 21: Input signal terminal (set input signal)
18, 22: Output signal terminal (pressure output signal)
19: Pressure type flow control system
23: Orifice
G₁: Carrier gas
G₄: Saturated steam of raw material
G₀: Mixed gas
G₅: Thin film formation gas
L₁, L₂: Flow passage
P, P₀: Pressure detector
T, T₀: Temperature detector
CV₁, CV₂: Control valve
V₁ to V₅: Valve
Ps: Input signal of set pressure
Pt: Temperature-corrected detection pressure value
Pd: Control valve drive signal
Pot: Output signal of regulated pressure (Temperature-corrected pressure detection signal of carrier gas G₁)

1. A raw material vaporizing and supplying apparatus connected to a process chamber, the apparatus comprising:
(a) a carrier gas supply source;
(b) a source tank in which a raw material is stored;
(c) a first flow passage through which a carrier gas G₁ is supplied from the carrier gas supply source to an internal upper space portion of the source tank;
(d) an automatic pressure regulating device installed on the first flow passage, wherein the automatic pressure regulating device controls internal pressure in the internal upper space portion of the source tank to a set first pressure;
(e) a second flow passage through which a mixed gas G₀ is supplied from the internal upper space portion of the source tank to the process chamber, wherein the mixed gas G₀ is a mixture of raw material steam generated from the raw material and the carrier gas;
(f) a flow control system that is installed on the second flow passage, wherein the flow control system automatically regulates a flow rate of the mixed gas G₀ that is supplied to the process chamber to a set first flow rate; and
(g) a constant temperature heating unit disposed to heat up the source tank, the first flow passage, and the second flow passage a set temperature,
wherein the raw material vaporizing and supplying apparatus supplies the mixed gas G₀ to the process chamber while controlling the internal pressure of the internal upper space portion of the source tank to the set first pressure.

2. The raw material vaporizing and supplying apparatus connected to the process chamber according to claim 1, wherein the first flow passage and the second flow passage are comprised of one or more pipe passages through which a fluid flows, and one or more distribution passages disposed inside the automatic pressure regulating device and the flow control system.

3. The raw material vaporizing and supplying apparatus connected to the process chamber according to claim 1, wherein the automatic pressure regulating device that controls pressure in the internal upper space portion of the source tank comprises
(i) a first control valve;
(ii) a first temperature detector and a first pressure detector that are provided on the downstream side of the first control valve;
(iii) a first arithmetic and control unit connected to receive a first detection value from the first pressure detector and a second detection value from the first temperature detector, wherein the first arithmetic and control unit performs a temperature correction of the first detection value received from the first pressure detector on the basis of the second detection value received from the first temperature detector in order to compute a second pressure of the carrier gas G₁, and the first arithmetic and control unit outputs a first control signal in order to control opening and closing of the first control valve in a direction in which a difference between the first pressure set in advance and the computed second pressure is lessened by comparing both of the first pressure and the computed second pressure; and
(iv) at least a first portion of a heater disposed to heat up one or more distribution passages through which the carrier gas G₁ flows to a predetermined temperature.

4. The raw material vaporizing and supplying apparatus connected to the process chamber according to claim 1, wherein the flow control system that supplies the mixed gas G₀ from the internal upper space portion of the source tank to the process chamber comprises
(i) a first control valve;
(ii) a first temperature detector and a first pressure detector that are provided on the downstream side of the first control valve;
(iii) an orifice provided on the downstream side of the first pressure detector;
(iv) a first arithmetic and control unit connected to receive a first detection value from the first pressure detector and a second detection value from the first temperature detector, wherein the first arithmetic and control unit performs a temperature correction of a flow rate of the mixed gas G₀ computed by use of the first detection value received from the first pressure detector, on the basis of the second detection value received from the first temperature detector in order to compute a second flow rate of the mixed gas G₀, and the first arithmetic and control unit outputs a first control signal in order to control opening and closing of the first control valve in a direction in which a difference between the first flow rate of the mixed gas G₀ set in advance and the computed second flow rate of the mixed gas G₀ is lessened by comparing both of the first flow rate and the computed second flow rate; and
(v) at least a first portion of a heater disclosed to heat up one or more distribution passages through which the mixed gas G₀ flows to a predetermined temperature.

5. The raw material vaporizing and supplying apparatus connected to the process chamber according to claim 1, wherein the raw material is a liquid raw material or a solid raw material that is supported by a porous support.

6. The raw material vaporizing and supplying apparatus connected to the process chamber according to claim 3, wherein the flow control system that supplies the mixed gas G₀ from the internal upper space portion of the source tank to the process chamber comprises
(i) a second control valve;
(ii) a second temperature detector and a second pressure detector that are provided on the downstream side of the second control valve;
(iii) an orifice provided on the downstream side of the second pressure detector;
(iv) a second arithmetic and control unit connected to receive a third detection value from the second pressure detector and a fourth detection value from the second temperature detector, wherein the second arithmetic and control unit performs a temperature correction of a flow rate of the mixed gas G₀ computed by use of the third detection value received from the second pressure detector on the basis of the fourth detection value received from the second temperature detector in order to compute a second flow rate of the mixed gas G₀, and the second arithmetic and control unit outputs a second control signal in order to control opening and closing of the second control valve in a direction in which a difference between the first flow rate of the mixed gas G₀ set in advance and the computed second flow rate of the mixed gas G₀ is lessened by comparing both of the first flow rate and the computed second flow rate; and
(v) at least a second portion of the heater disclosed to heat up one or more distribution passages through which the mixed gas G₀ flows to the predetermined temperature.
